(19) United States
(12) Patent Application Publication
(10) Pub. No.: US 2009/0221149 A1
(43) Pub. Date: Sep. 3, 2009

(54) MULTIPLE PORT GAS INJECTION SYSTEM UTILIZED IN A SEMICONDUCTOR PROCESSING SYSTEM

(76) Inventors: Edward P. Hammond, IV, Hillsborough, CA (US); Rodolfo P. Belen, San Francisco, CA (US); Nicolas Gani, San Jose, CA (US); Jing Zou, Sunnyvale, CA (US); Meihua Shen, Fremont, CA (US); Michael D. Willwerth, Campbell, CA (US); David Palagashvili, Mountain View, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/039,262

(22) Filed: Feb. 28, 2008

(51) Int. Cl. H01L 21/306

(52) U.S. Cl. 438/706; 156/345.33; 257/E21.215

(57) ABSTRACT

An apparatus having a multiple gas injection port system for providing a high uniform etching rate across the substrate is provided. In one embodiment, the apparatus includes a nozzle in the semiconductor processing apparatus having a hollow cylindrical body having a first outer diameter defining a hollow cylindrical sleeve and a second outer diameter defining a tip, a longitudinal passage formed longitudinally through the body of the hollow cylindrical sleeve and at least partially extending to the tip, and a lateral passage formed in the tip coupled to the longitudinal passage, the lateral passage extending outward from the longitudinal passage having an opening formed on an outer surface of the tip.

### BACKGROUND

1. Field of the Invention

Embodiments of the present invention generally relate to semiconductor processing systems. More specifically, embodiments of the invention relates to an apparatus having multiple port gas injection system in a semiconductor processing system.

2. Description of the Related Art

Reliably producing sub-half micron and smaller features is one of the key technologies for the next generation of very large scale integration (VLSI) and ultra large-scale integration (ULSI) of semiconductor devices. However, as the limits of circuit technology are pushed, the shrinking dimensions of interconnects in VLSI and ULSI technology have placed additional demands on processing capabilities. Reliable formation of device structures is important to VLSI and ULSI success and to the continued effort to increase circuit density and quality of individual substrates and die.

Etching is one of many processes used for fabricating device structures. One problem associated with a conventional etch process is the non-uniformity of etch rate across the substrate due to a substrate edge effect. For example, ion plasma distribution across the substrate during processing are typically asymmetrical, resulting in a center-high edge-low or a center-low edge-high etch rate distribution across the substrate. Non-uniformity of etch rate may result in features formed on the substrate having different profiles and dimensions across the substrate surface. Furthermore, lateral etch rate non-uniformity also results in non-uniform critical dimensions of the structures formed by the etch process. Herein lateral etch rate non-uniformity is defined as a ratio of a difference between the maximal and minimal lateral etch rate to the sum of such values across the substrate. In many etch processes, the lateral etch rate at peripheral locations (i.e., near an edge of the substrate) is higher than the etch rate near a center of the substrate.

During the etch process, non-volatile by-products may passivate the sidewalls of the structures being formed and, as such, reduce the etch rate. or cause growth of critical dimensions during etching. Non-uniformity of the passivation rate across the substrate maybe caused by a higher concentration of etch by-products near the center of the substrate as compared to the peripheral region. In operation, a generally concentric pattern of exhaust pumping in the etch process chamber results in low concentration of the by-products near the edge of the substrate and, correspondingly, in a high local lateral etch rate as compared to the center of the substrate.

As such, structures being formed using conventional etch processes are typically over-etched in the peripheral region as compared to the central region of the substrate and experience less growth or even loss of critical dimensions. A loss of accuracy for topographic dimensions (e.g., critical dimensions (CDs), or smallest widths) of the etched structures in the center or peripheral regions of the substrates may significantly affect performance and increase costs of fabricating the integrated circuits and micro-electronic devices.

Therefore, there is a need for improving etching rate uniformity across a substrate.

### SUMMARY

Embodiments of the invention include an apparatus having a multiple gas injection port system for providing a high uniform etching rate across the substrate. In one embodiment, an apparatus includes a gas nozzle for a semiconductor processing chamber. The nozzle has a hollow cylindrical body having a first outer diameter defining a hollow cylindrical sleeve and a second outer diameter defining a tip. A longitudinal passage is formed through the hollow cylindrical sleeve and at least partially extending to the tip of the body. A lateral passage breaks through the tip to the longitudinal passage. The lateral passage extends outward from the longitudinal passage to an opening formed on an outer surface of the tip.

In another embodiment, a semiconductor processing system includes a processing chamber having a chamber wall and a chamber lid defining a process volume, an annular ring having a plurality of injection ports formed therein positioned above the chamber wall and below the chamber lid, a plurality of nozzles each inserted within the plurality of injection ports configured to inject processing gas to the process volume, wherein the nozzles have an opening angled downwardly relative to a center line of the nozzle configured to inject processing gas to a predetermined position of the process volume.

In yet another embodiment, a method of etching a substrate disposed in a processing chamber includes providing a substrate into a processing chamber, supplying a reacting gas to a center region of the substrate surface though first group of injection ports disposed in a center region of the processing chamber, and supplying a passivation gas to a periphery region of the substrate surface through a second group of injection ports, wherein respective one of the second group of injection ports has a respective nozzle disposed therein, the nozzle having an opening oriented downwardly to direct passivation gas to the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 is a schematic cross sectional diagram of an exemplary semiconductor substrate processing apparatus comprising a multiple port gas injection system in accordance with one embodiment of the invention;

FIGS. 2A-2C are a schematic top and cross sectional view of one embodiment of an annular ring having multiple gas passages formed therein;

FIG. 3A-B are cross sectional views of different embodiments of a nozzle that may be used in the multiple port gas injection system of FIG. 1;

FIG. 4 is a top view of a multiple port gas injection system; and

FIG. 5 is a perspective drawing of an exemplary semiconductor substrate processing apparatus having one embodiment of a multiple port gas injection system.

It is to be noted, however, that the appended drawings illustrate only typical embodiments of this invention and are therefore not to be considered limiting of its scope, for the invention may admit to other equally effective embodiments.

To facilitate understanding, identical reference numerals have been used, where possible, to designate identical elements that are common to the figures.

### DETAILED DESCRIPTION

Embodiments of the present invention include an apparatus having a multiple injection port system for etching topographic structures in material layers on a substrate with high etching rate uniformity. In one embodiment, the multiple gas injection port may supply different gases, such as a passivation gas and a reacting gas, individually and respectively at center and edge of the processing chamber to a substrate surface, thereby efficiently adjusting etch rate distribution across the substrate surface. The apparatus is generally used during etching of semiconductor devices, circuits and the like. Although invention is illustratively described in a semiconductor substrate etching apparatus, such as, a DPS® etch reactor, available from Applied Materials, Inc. of Santa Clara, Calif., the invention may be utilized in other processing systems, including etch, deposition, implant and thermal processing, or in other application where high gas distribution uniformity across a substrate and/or a processing chamber is desired.

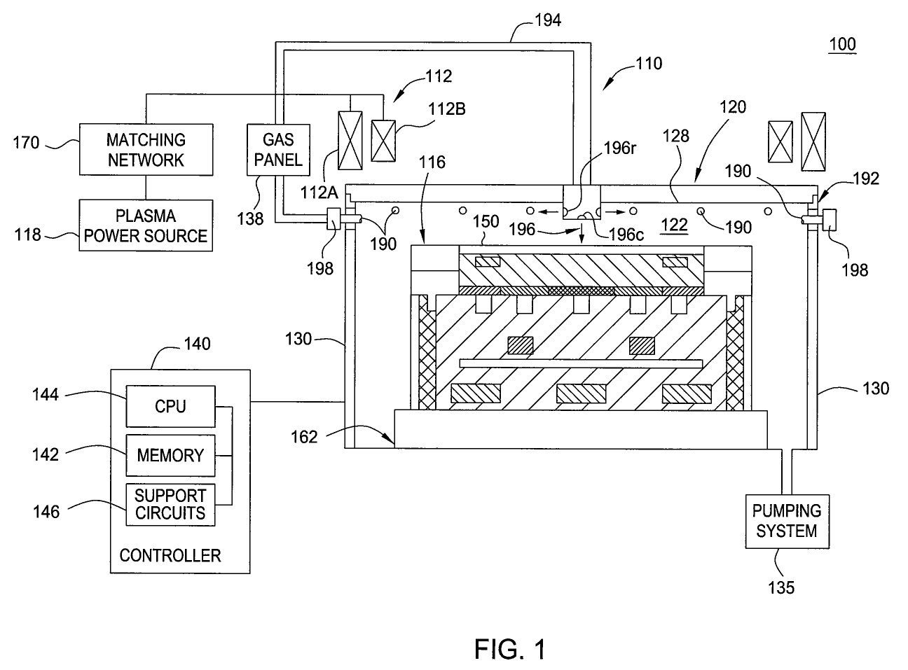

FIG. 1 depicts a schematic diagram of an exemplary processing chamber 100 having a multiple port gas injection system 110 that may illustratively be used to practice the invention. The particular embodiment of the processing chamber 100 shown herein is an etch reactor and is provided for illustrative purposes and should not be used to limit the scope of the invention.

A controller 140 including a central processing unit (CPU) 144, a memory 142, and support circuits 146 is coupled to the processing chamber 100. The controller 140 controls components of the processing chamber 100, processes performed in the processing chamber 100, as well as may facilitate an optional data exchange with databases of an integrated circuit fab.

The processing chamber 100 generally includes a conductive body (wall) 130 and a removable lid 120 that enclose a process volume 122. The removable lid 120 has a bottom surface that forms as a ceiling 128 of the processing chamber 100. In the depicted embodiment, the removable lid 120 is a substantially flat dielectric member. Other embodiments of the processing chamber 100 may have other types of lids, e.g., a dome-shaped ceiling. Above the removable lid 120 is disposed an antenna 112 comprising one or more inductive coil elements (two co-axial coil elements 112A and 122B are illustratively shown). The antenna 112 is coupled, through a first matching network 170, to a radio-frequency (RF) plasma power source 118. A pumping system 135 is coupled to the processing chamber 100 to facilitate evacuation and maintenance of process pressure. A substrate support assembly 116 is disposed in a bottom portion of the processing chamber 100 readily to receive a substrate 150 disposed thereon. The multiple port gas injection system 110 is disposed on a top portion of the processing chamber 100 adjacent to the ceiling 128 facing an upper surface of the substrate support assembly 116. The multiple port gas injection system 110 is coupled to a gas panel 138 utilized to supply process gasses to the process volume 122 of the chamber 100.

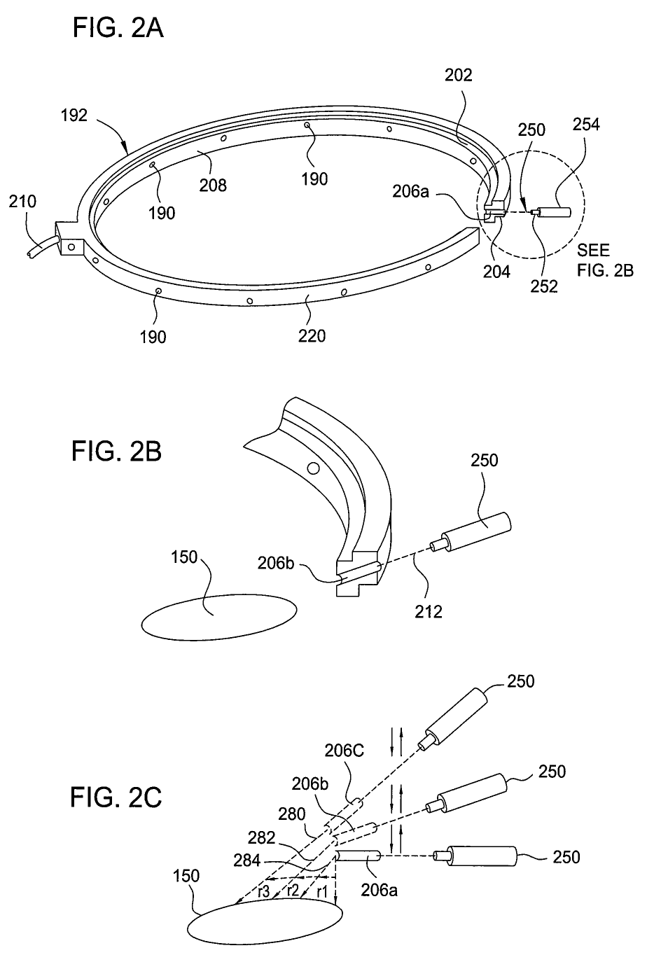

In one embodiment, the multiple port gas injection system 110 has a plurality of injection ports 190, 196 configured to supply processing gas to the process volume 122. A first group of the injection ports 190 is formed in an annular ring 192 disposed around top portion of the sidewall 130 and below the ceiling 128. The annular ring 192 interfaces with and partially occludes an edge shoulder step 172 of the removable lid 120. The injection ports 190 of the first group are evenly spaced about an interior surface of the annular ring 192 to facilitate supplying processing gas from gas panel 138 through a gas manifold 198 to the process volume 122. Details of the annular ring 192 and the first group of injection ports 190 will be further discussed below with referenced to FIGS. 2A-C.

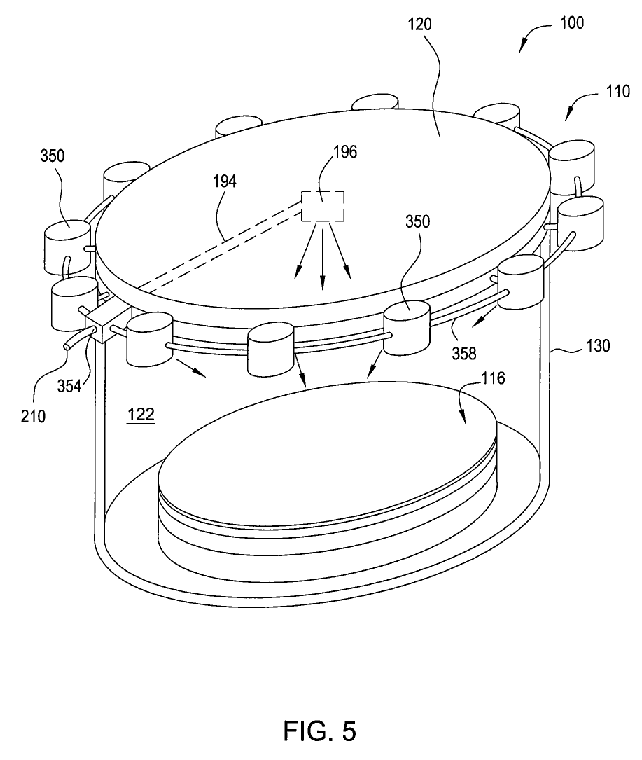

A second group of injection ports 196 is disposed in the ceiling 128 below the removable lid 120. The second group of injection ports 196 is coupled to the gas panel 138 through a gas supply line 194. The gas supply line 194 may be disposed externally to the processing chamber 100 coupling the injection ports 196 to the gas panel 138. Alternatively, the gas supply line 194 may be embedded within the removable lid 120, as will be further discussed with referenced to FIG. 5. In one embodiment, the second group of injection ports 196 may be disposed in a center region of the ceiling 128 having one or more center injection ports injecting processing gas to a center portion/zone of the process volume 122. In another embodiment, the second group of the injection ports 196 may be covered in a showerhead (not shown) attached to the ceiling 128 of the removable lid 120. The showerhead may have one or more concentric zones. Each zone feeds by processing gases provided by one or more of the ports 196. It is contemplated that different numbers, dimensions, profiles, and distributions of the ports 196 may be utilized to distribute different amount of processing gas into the process volume 122 across the substrate 150. In the embodiment depicted in FIG. 1, the second group of injection ports 196 is formed in a center region/zone of the ceiling 128. In one embodiment, the ports 196 include at least one port 196c facing downward and a plurality of ports 196r facing radially outward so that the ratio of processing gases flow toward the center and edge of the substrate 100 may be controlled. Optionally, the rates and/or types of the gases provided to each port 196c, 196r may be independently controlled.

FIG. 2A is a schematic top and partial cross sectional view of the annular ring 192 of FIG. 1 having the first group of injection ports 190 formed therein. An outer gas supply line 210 is coupled to the ring 192 to supply processing gas from the gas panel 138 to the injection ports 190. The annular ring 192 has an inner surface 208 and an outer surface 220 defining an inner and an outer diameter of the ring 192. An interior shoulder 202 formed in an upper portion of the inner surface 208 to receive the edge shoulder step 172 of the removable lid 120 so that the lid 120 rests on the annular ring 192, as shown in FIG. 1. An exterior shoulder 204 is formed in a lower portion of the outer surface 220 and is configured to engage the chamber sidewall 130. The annular ring 192 is sized and shaped to mate with the edge shoulder 172 of the removable lid 120 and the chamber sidewall 130 when installed in the processing chamber 100. In one embodiment, the annular ring 192 may be fabricated from process compatible materials, such as ceramic, metal or other suitable material. Examples materials suitable for fabricating the annular ring 192 include anodized materials, such as Al₂O₃ or anodized Al, yttrium containing material, such as Y₂O₃, or ceramic, such as Al₂O₃ or silicon carbide, metallic materials and the like.

In one embodiment, a plurality of injection ports 190 are evenly spaced around the annular ring 192. The number and locations of injection port 190 may be selected to provide a desired gas distribution. In the embodiment depicted therein, twelve injection ports are formed in the annular ring 192.

Each injection port 190 has a radial cylindrical passage 206a configured to accept a nozzle 250. The passage 206a may be machined or otherwise formed in within the annular ring 192. The radial cylindrical passage 206a is sized to securely receive the nozzle 250.

In one embodiment, the nozzle 250 includes a hollow cylindrical sleeve 254 and a tip 252. The sleeve 254 comprises the main body of the nozzle 250 sized to fit within the passage 206a. The tip 252 of the nozzle 250 extends from the sleeve 254 and projects radially inward from the inner surface 208 of the ring 192 into the volume 122 of the processing chamber 100. The nozzle 250 is configured to be readily removable from the radial cylindrical passage 206a to facilitate ease of replacement. In one embodiment, the nozzle is fabricated from process compatible materials, such as ceramic or metal material. Examples suitable nozzle materials include, but not limited to, anodized materials, such as Al₂O₃ or anodized Al, yttrium containing material, such as Y₂O₃, or other similar ceramic, such as Al₂O₃ or silicon carbide, or other metallic materials.

In one embodiment, the radial cylindrical passage 206a may be formed substantially horizontal relative to a substrate surface disposed in the processing chamber 100 to receive the nozzle 250 in a substantially horizontal orientation. Upon supplying processing gases, the nozzle 250 injects the processing gas inward to a desired position of the substrate surface. Furthermore, the position of each nozzle 250 and/or the injection angle of each nozzle 250 relative to the substrate surface may be individually arranged so as to inject gas flow to a desired region or the substrate surface. For example, the radial cylindrical passage 206a formed in the annular ring 192 may have an injection angle below a horizontal plane. In the embodiment of a radial cylindrical passage 206b depicted in FIG. 2B, the radical cylindrical passage 206b may be formed in the ring 192 at an angle downward relative to a horizontal plane to facilitate accurate injection of gases to a targeted region on the substrate surface. The injection angle and position of the nozzles 250 from which processing gases are directed to the substrate surface provide good control over lateral etching profile across the substrate.

FIG. 2C depicts different trajectories 280, 282, 284 for the processing gases injected from the nozzles 250 disposed in radial cylindrical passages 206c, 206b and 206a. Different angles of the processing gas trajectories 280, 282, 284 from nozzles 250 to the substrate surface result in different radial distances r1, r2, r3 from the centerline of the substrate 150. Accordingly, by selection of the angle which directs the processing gases to the substrate surface, different distribution profile of processing gases may be obtained across the substrate surface. As the gas flow distribution profile may be adjusted, the uniformity of the center-edge gas flow across the substrate surface may be efficiently improved, thereby assisting in controlling the etch results (e.g., etch rate, feature profile, microloading effect) across the substrate in an uniform manner and maintaining a desired topographic dimension of features formed on the substrate 150.

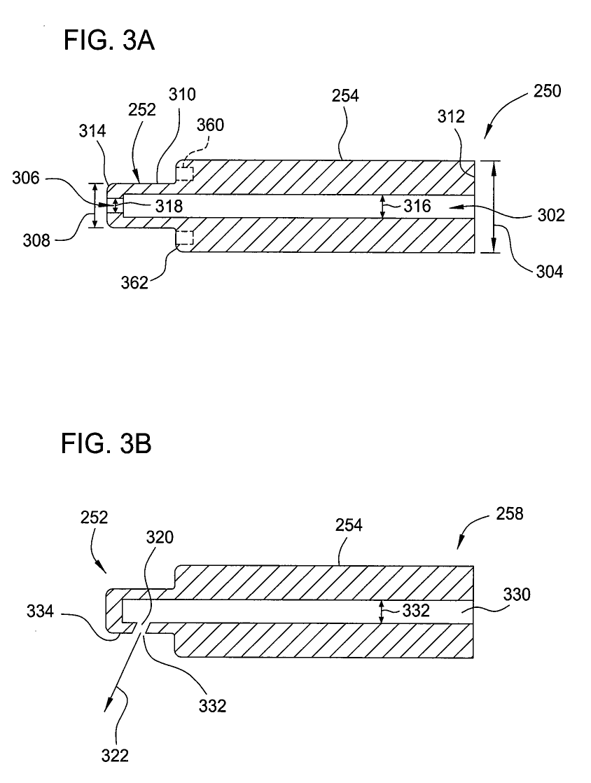

FIG. 3A depicts a cross sectional view of one embodiment of nozzle 250. The nozzle 250 includes a hollow cylindrical body. The body has the hollow cylindrical sleeve 254 and the tip 252. The tip 252 extends from the hollow cylindrical sleeve 254. The hollow cylindrical sleeve 254 has a first outer diameter 304 and the tip 252 has a second outer diameter 308. The second outer diameter 308 is smaller than the first outer diameter 304, thereby defining the tip 252. In one embodiment, the first outer diameter 304 is about 50 percent greater than the second outer diameter 308. In one embodiment, the first outer diameter 304 is between about 15.5 mm and about 16 mm and the second outer diameter 308 is between about 7.0 mm and about 7.5 mm.

A face 362 is formed on the exterior of the nozzle 250 between the tip 252 and the sleeve 254. The face 362 may be perpendicular to a central axis of the nozzle 250. In one embodiment, an o-ring gland 260 (shown in phantom) may be formed in the face 362 to accommodate the o-ring which may be utilized to prevent leakage between the nozzle 250 and the ring 192.

The nozzle 250 includes a longitudinal passage formed within hollow cylindrical sleeve 254 and the tip 252. The longitudinal passage includes a first passage 302 and a second passage 306. The first passage 302 originates from a first end 312 of the nozzle 250 and extends through the body of the hollow cylindrical sleeve 254. The first passage 302 further extends at least partially into the tip 252, connecting to the second passage 306. The second passage 306 coaxially aligned with the first passage 304 and extends longitudinally from the end of the first passage 304 to an second end 314 of the tip 252 of the nozzle 250. Upon supplying a processing gas, the processing gas is delivered from the first passage 302 to the second passage 306 and injected through the second passage 306 to the substrate surface.

In one embodiment, the first passage 302 has a first inner diameter 306 and the second passage 306 has a second inner diameter 318 that smaller than the first inner diameter 316. The first inner diameter 316 in the first passage 302 may transition sharply into the second inner diameter 318 in the second passage 306, for example, at about a 90 degree interface. In one embodiment, the second inner diameter 318 is about four times smaller than the first inner diameter 316. In one embodiment, the first inner diameter 316 is between about 3.0 mm and about 3.5 mm and the second inner diameter 318 is between about 0.5 mm and about 1 mm.

FIG. 3B depicts another embodiment of a nozzle 258 that may be utilized with the ring 192 of FIGS. 2A-B. The nozzle 258 has a longitudinal passage 330 having a uniform inner diameter 332 formed through the hollow cylindrical sleeve 254 and extending at least partially to the tip 252. The longitudinal passage 330 may be coaxial or parallel to a centerline of the nozzle 258. The longitudinal passage 330 is held in an orientation substantially in a horizontal plane parallel to the substrate surface by the ring 192. A lateral passage 320 is formed at the tip portion 252 of the nozzle 258 and connected to the longitudinal passage 330. The lateral passage 320 extends outward from the longitudinal passage 330 to an opening 332 formed on an outer surface 334 of the tip 252. In one embodiment, the opening 332 has a width between about 0.5 mm and about 1.0 mm.

In one embodiment, the lateral passage 320 forms an acute angle with the longitudinal passage 330. The injection angle may be formed substantially from about 15 degree to about 90 degree relative to the longitudinal passage 330. The injection angles defined by the lateral passage 320 relative to the longitudinal passage 330 sets the trajectory 322 of the processing gas injected to the substrate surface. Accordingly, by selection of the angle formed by lateral passage 320 relative to the substrate surface, locations where the processing gases is delivered to the substrate surface may be efficiently controlled as desired, thereby providing a desired gas distribution profile formed across the substrate surface. As the gas flow distribution profile may be set by using a nozzle 258 with a desired orientation of the lateral passage 320, the center-to-edge gas flow uniformity across the substrate surface may be efficiently improved, thereby facilitating control of the etching results. Thus the substrate may be etched in an uniform manner while maintaining a desired topographic dimension of features formed on the substrate 150. In the embodiment where this particular type of nozzle 258 is used, the radial cylindrical passage 206a of the ring 192 may be formed in a substantially perpendicular orientation relative to a centerline of the ring 192, so that the opening 322 of the lateral passage 320 formed in the nozzle 258 is pointed downward at a desired angle relative to the substrate surface.

Therefore, not only by controlling the injection angle of the radial cylindrical passage 206a, 206b formed in the annular ring 192 as shown in FIGS. 2A-C, the designs of the nozzles 250, 258 may be selected to adjust the injection angle of the processing gas to the substrate surface. By adjusting the angle of the radial cylindrical passage 206a, 206b formed in the annular ring 192 and/or lateral passage 320 formed in the nozzle 258, the gas flow distribution profile across the substrate surface may be efficiently controlled to achieve desired etching profile on the substrate.

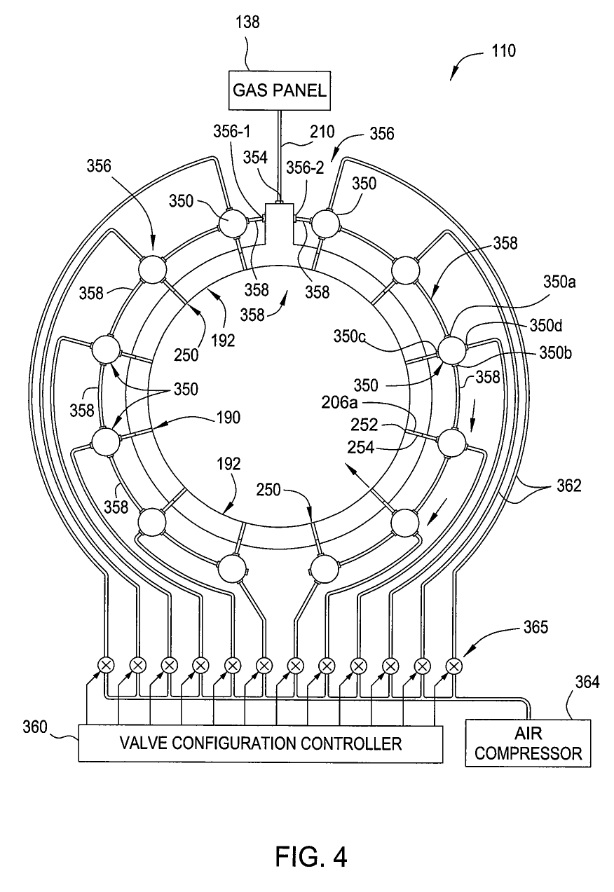

FIG. 4 depicts a top view of the multiple port gas injection system 110 utilized to control the gas injection through the first group of gas injection ports 190. The first group of gas injection ports 190 are disposed in a polar array about the annular ring 192. The injection ports 190 are connected to respective valves 350. In one embodiment, the open state of each valve 350 is independently controlled. The valve 350 may be pneumatically controlled as shown in FIG. 4. The valve 350 includes an input flow-through port 350a, an output flow-through port 350b, a controlled gas outlet port 350c, and a pneumatic pressure control input port 350d. The outlet port 350c provides a controlled process gas flow to the corresponding nozzle 250 to inject processing gas to a predetermined position on the substrate surface.

During operation, processing gas supplied from the gas panel 138 flows through the outer gas supply line 210 through an input port 354 formed on the annular ring 192. Gas supply outlet ports 356-1, 356-2 are formed in the annular ring 192 and are connected to the inlet port 354. A series of disconnectable gas flow lines 358 serially connect the valves 350 to the outlet ports 356-1, 356-2 of the annular ring 192. The gas flow lines 358 are connected to the gas supply outlet ports 356-1, 356-2 respectively to deliver the processing gas from the gas supply ports 356-1, 356-2 to a corresponding set of the valves 350 connecting to the gas injection ports 190. The processing gas flows through the gas supply line 358 to the input flow-through port 350a of the valve 350. The processing gas flows from the input flow-through port 350a to the output flow-through port 350b. Compressed air pressure at the control input port 350d determines whether the process gas is provided to the gas outlet port 350c. The remaining gas other than diverted to the gas outlet port 350c is passed through the output flow-through port 350b compressed to the flow lines 358 to the successive valve 350.

Alternatively, the process gases ma be distributed recursively to the processing chamber 100 to ensure balanced flow to nozzle 250. The gas line from introduction of the gas to each nozzle 250 exiting throughout to the interior volume 122 is substantially equal so that flow resistance is substantially equal for all gas lines 358.

A valve configuration processor 360 controls on and off, or any combination, of all of the valves 350 via valve control links 362. Each valve 350 has an on-off mode controlled by the valve configuration processor 360 to provide or terminate gas flow to each corresponding gas injection port 190. When the valve 350 is switched to an “on” mode, the processing gas is individually and separately supplied to the corresponding gas injection port 190. In contrast, when the valve 350 is switched to an “off” mode, the gas flow supplied to its corresponding gas injection port 190 is terminated without affecting the flow of gas to the other valves. In an embodiment wherein the valves 350 are pneumatic valves, the control links 362 are designed as pneumatic, e.g., air, tubes to avoid the presence of electrical conductors close to the coil antennas 112A, 112B.

An air compressor 364 furnishes a desired pressure to an array of solenoid (e.g., electrically controlled) valves 365 that control application of the pressurized air to pneumatic control inputs 350a of the respective pneumatic valves 350. The gas flow through the series of the valves 350 in the left side of FIG. 4 is counter-clockwise while gas flow through the serious of valves 350 in the right side of the FIG. 4 is clockwise. Alternatively, the valves 350 may be controlled electronically or by other suitable manner in the conventional practice.

FIG. 5 depicts a perspective drawing of the semiconductor substrate processing chamber 100 having the multiple port gas injection system 110 implemented therein. Upon installation of the multiple port gas injection system 110, the plurality of valves 350 connected by the gas flow lines 358 are disposed around periphery region outside of the processing chamber 100. The second group of injection port 196 is located in the center region below the removable lid 120. The second group of injection port 196 may be controlled by another separate and individual valve (not shown) similar to the valve 350 depicted in FIG. 4. The gas supply line 194 connects the second group of the injection port 196 to the outer gas supply line 210 further to the gas panel 138. The gas supply line 194 coupled to the second group of injection port 196 may be embedded within the removable lid 120 or by any other suitable manner internal or external to the processing chamber 100.

By utilizing the multiple port gas injection system 110, the processing gases may be supplied to the processing chamber 100 through different injection ports 196, 190 across the substrate surface.

In one embodiment, a passivation gas may be dispersed into the processing chamber 100 through the first group of injection ports 190 during etching while a reacting gas may be supplied to the processing chamber 100 through the second group of injection ports 196. The passivation gas supplied through the first group of injection ports 190 are dispersed predominantly to a periphery region of the substrate surface while the reacting gas is directed predominately to the center of the substrate. The flow rate of the passivation gas supplied through each individual injection port 190 may be selectively controlled to facilitate a high concentration of such gas in a certain peripheral region on the substrate surface. The reacting gas supplied from the second group of injection port 196 may be controlled at different gas flow rate to result different concentration of reacting gas between the center and the periphery region of the substrate.

During etching, a portion of the etchants gas and by-products from the etching process are pumped away. A remaining portion of the by-products are re-deposited on sidewalls of the structures formed on the substrate, thereby reducing lateral rate and increasing critical dimensions during etching. In some embodiment, the concentration of such by-products may be depleted in the peripheral region faster than in the center region of the substrate, thereby resulting in low concentration of the by-product in the peripheral region and causing an increase in the etch rate in the peripheral region and less growth or even loss in critical dimensions during etching. By supplying the passivation gas from the first group of injection ports 190 to the periphery region of the substrate, the passivation gas assists forming a passivation film on sidewalls of the structures being formed in the peripheral region of the substrate. The chemistry of the passivation gas is selected such that the greater degree of polymerization potential enhances higher amount of passivation film deposited on the sidewalls of the structures which is chemically similar to the by-product of the etching process. The flow rate and degree of plasma dissociation of the passivation gas may be selectively adjusted to compensate for depletion of the by-products of the process to reduce the lateral etch rate in the peripheral region of the substrate, thereby providing a substantially uniform etching rate and feature scale critical dimensions across the substrate surface.

In one exemplary embodiment, a gate structure having silicon containing layer may be etched utilizing this processing chamber 100 with the multiple port gas injection system 110. The passivation gas that may be used in this etching process includes one or more fluorosilane (SiF₄), silane (SiH₄), silicon tetrachloride (SiCl₄), CHF₃, CH₂F₂, CH₃F, HBr or the like. The reacting gas includes halogen containing gas, such as Cl₂, HBr, BCl₃, CF₄ and the like. Some dilution gas, such as N₂, He, Ar or the like, may also be supplied to the processing chamber 100 during etching. In one embodiment, the passivation gas may be supplied to the processing gas at a flow rate between about 0 sccm and about 200 sccm. The reacting gas may be supplied to the processing gas at a flow rate between about 100 sccm and about 500 sccm. The dilution gas may be supplied to the processing gas at a flow rate between about 0 sccm and about 200 sccm.

While the foregoing is directed to embodiments of the present invention, other and further embodiments of the invention may be devised without departing from the basic scope thereof, and the scope thereof is determined by the claims that follow.

What is claimed is:

1. A nozzle for a semiconductor processing apparatus, comprising:
a hollow cylindrical body having a first outer diameter defining a hollow cylindrical sleeve and a second outer diameter defining a tip;
a longitudinal passage formed through the hollow cylindrical sleeve and at least partially extending to the tip of the body; and
a lateral passage formed in the tip coupled to the longitudinal passage, the lateral passage extending outward from the longitudinal passage to an opening formed on an outer surface of the tip.

2. The nozzle of claim 1, wherein the first outer diameter is greater than the second outer diameter.

3. The nozzle of claim 1, wherein the lateral passage is originated at an acute angle relative to the longitudinal passage.

4. The nozzle of claim 3, wherein the angle is substantially from about 15 degree to about 90 degree to the longitudinal passage.

5. The nozzle of claim 1, wherein the opening has a diameter between about 0.5 mm and about 1 mm.

6. A semiconductor processing system, comprising:
a processing chamber having a chamber wall and a chamber lid defining a process volume;
an annular ring having a plurality of injection ports formed therein positioned above the chamber wall and below the chamber lid; and
a plurality of nozzles, respective one of the nozzles disposed in a respective one of the plurality of injection ports, wherein the nozzles have an opening oriented to direct gas downwardly to the process volume.

7. The semiconductor processing system of claim 6, further comprising:
at least one center injection port formed in a center portion of the chamber lid.

8. The semiconductor processing system of claim 6, further comprising:
a source of passivation gas coupled to the nozzles disposed in the annular ring.

9. The semiconductor processing system of claim 7, further comprising:
a source of reacting gas coupled to the center injection port.

10. The semiconductor system of claim 6, wherein the opening of each of the nozzle is oriented downward relative to a horizontal plane.

11. The semiconductor system of claim 6, wherein an angle of the opening relative to the horizontal plane is substantially from about 15 degrees to about 90 degrees relative to the horizontal plane.

12. The semiconductor system of claim 6, wherein the nozzle further comprises:
a hollow cylindrical body having a first outer diameter defining a hollow cylindrical sleeve and a second outer diameter defining a tip;
a longitudinal passage formed longitudinally through the body of the hollow cylindrical sleeve and at least partially extending to the tip; and
a lateral passage formed in the tip coupled to the longitudinal passage, the lateral passage extending outward from the longitudinal passage to the opening formed on an outer surface of the tip.

13. The semiconductor system of claim 12, wherein the first outer diameter is greater than the second outer diameter.

14. The semiconductor system of claim 12, wherein the first outer diameter is between about 15.5 mm and about 16 mm and the second outer diameter is between about 7.0 mm and about 7.5 mm.

15. The semiconductor system of claim 6, wherein the opening has a width between about 0.5 mm and about 1 mm.

16. The semiconductor system of claim 6, wherein the nozzle is fabricated from a ceramic or metallic material.

17. The semiconductor system of claim 6, wherein the nozzle is fabricated from Al₂O₃, anodized Al, or Yr containing material.

18. A method of etching a substrate disposed in a processing chamber, comprising:
providing a substrate into a processing chamber;
supplying a reacting gas to a center region of the substrate surface though first group of injection ports disposed in a center region of the processing chamber; and
supplying a passivation gas to a periphery region of the substrate surface through a second group of injection ports, wherein respective one of the second group of injection ports has a respective nozzle disposed therein, the nozzle having an opening oriented downwardly to direct passivation gas to the substrate.

19. The method of claim 18, wherein the opening of each of the nozzle is oriented downward relative to a horizontal plane.

20. The method of claim 18, wherein an injection angle of the opening relative to the horizontal plane is substantially from about 15 degrees to about 90 degrees relative to the horizontal plane.

21. The method of claim 18, wherein the opening of each nozzle has the independently injection angle relative to the horizontal plane.

22. The method of claim 18, wherein the passivation gas is selected from a group consisting of fluorosiliance (SiF₄), silane (SiH₄), silicon tetrachloride (SiCl₄), CHF₃, CH₂F₂, CH₃F and HBr.

23. The method of claim 18, wherein the reacting gas is selected from a group consisting of Cl₂, HBr, BCl₃, CF₄.

24. The method of claim 18, wherein the concentration of the passivation gas is controlled to be higher in the periphery region of the substrate surface than the center region.
